(19) United States
(12) Patent Application Publication
(10) Pub. No.: US 2026/0033216 A1
(43) Pub. Date: Jan. 29, 2026

(54) PROTECTIVE LAYER, AND DISPLAY APPARATUS INCLUDING THE PROTECTIVE LAYER

(71) Applicant: Samsung Display Co., Ltd., Yongin-Si (KR)

(72) Inventor: Jonghwan Cho, Yongin-si (KR)

(21) Appl. No.: 19/249,094

(22) Filed: Jun. 25, 2025

(30) Foreign Application Priority Data
Jul. 23, 2024 (KR) 10-2024-0097494

(51) Int. Cl. H10K 59/80; C03C 17/36

(52) U.S. Cl. CPC H10K 59/873; C03C 17/3649; C03C 17/3657; H10K 59/879; C03C 2217/213; C03C 2217/228; C03C 2217/252; C03C 2217/734; C03C 2217/76

(57) ABSTRACT

Provided are a protective layer and a display apparatus including the protective layer. The protective layer includes a base layer, a first high refractive layer disposed on the base layer and including titanium and niobium, a first low refractive layer disposed on the first high refractive layer and including silicon, a second high refractive layer disposed on the first low refractive layer, the first high refractive layer and the second high refractive layer including a same material, a second low refractive layer disposed on the second high refractive layer, the first low refractive layer and the second low refractive layer including a same material, an anti-fingerprint layer disposed on the second low refractive layer and including a perfluorinated compound, and a metal layer interposed between the first high refractive layer and the first low refractive layer and including aluminum.

### CROSS-REFERENCE TO RELATED APPLICATION

This application is based on and claims priority under 35 U.S.C. § 119 to Korean Patent Application No. 10-2024-0097494, filed on Jul. 23, 2024, in the Korean Intellectual Property Office, the disclosure of which is incorporated by reference herein in its entirety.

### BACKGROUND

### 1. Field

One or more embodiments relate to a protective layer and a display apparatus including the protective layer, and more particularly, to a protective layer in which occurrence of cracks may be reduced during folding of a display apparatus, and a display apparatus including the protective layer.

### 2. Description of the Related Art

Display apparatuses can be formed by coupling various elements to each other. In detail, a display apparatus can be formed by coupling a display panel including a display element to a cover window for protecting the display panel. Such a display apparatus may further include a protective layer to prevent or reduce the occurrence of scratches on an upper surface of the cover window, and the protective layer may include an anti-reflection layer for reducing the reflectivity of externally incident light to improve visibility of the display apparatus.

Display apparatuses may be utilized as various electronic apparatuses. For example, a display apparatus may be a mobile electronic apparatus, such as a smartphone. Such an electronic apparatus may be a foldable electronic apparatus in which part of a display surface is folded to reduce the overall size of the electronic apparatus and also increase the area of the display surface of the electronic apparatus.

### SUMMARY

A foldable display apparatus may have cracks that occurred in the protective layer due to damage to the anti-reflection layer caused during folding of the display apparatus.

One or more embodiments include a protective layer in which occurrence of cracks may be reduced during folding of a display apparatus, and a display apparatus including the protective layer. However, aspects of embodiments according to the disclosure are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a protective layer includes a base layer, a first high refractive layer disposed on the base layer and including titanium and niobium, a first low refractive layer disposed on the first high refractive layer and including silicon, a second high refractive layer disposed on the first low refractive layer, the first high refractive layer and the second high refractive layer including a same material, a second low refractive layer disposed on the second high refractive layer, the first low refractive layer and the second low refractive layer including a same material, an anti-fingerprint layer disposed on the second low refractive layer and including a perfluorinated compound, and a metal layer interposed between the first high refractive layer and the first low refractive layer and including aluminum.

The first high refractive layer may include titanium-niobium oxide, and the first low refractive layer may include silicon oxide.

Each of the first high refractive index layer and the second high refractive index layer may have a refractive index of about 1.7 to about 3.0.

Each of the first low refractive index layer and the second low refractive index layer may have a refractive index of about 1.3 to about 1.6.

The first high refractive layer may include a substitutional solid solution in which a portion of titanium atoms of titanium oxide is replaced by niobium atoms.

The first high refractive layer may include Ti₁₄Nb₃O₃₅, and the first low refractive layer may include SiO2.

A thickness of the metal layer may be about 0.5 nm to 20 nm.

The protective layer may further include an auxiliary layer interposed between the metal layer and the first low refractive layer, the first high refractive layer and the auxiliary layer including a same material.

According to one or more embodiments, a protective layer includes a base layer, a first high refractive layer disposed on the base layer and including titanium and niobium, a first low refractive layer disposed on the first high refractive layer and including silicon, a second high refractive layer disposed on the first low refractive layer, the first high refractive layer and the second high refractive layer including a same material, a second low refractive layer disposed on the second high refractive layer, the first low refractive layer and the second low refractive layer including a same material, an anti-fingerprint layer disposed on the second low refractive layer and including a perfluorinated compound, and a metal layer interposed between the first low refractive layer and the second high refractive layer and including aluminum.

The protective layer may further include an auxiliary layer interposed between the metal layer and the first low refractive layer, the first high refractive layer and the auxiliary layer including a same material.

According to one or more embodiments, a display apparatus includes a display panel, a cover window disposed on the display panel, and a protective layer disposed on the cover window. The protective layer includes a base layer, a first high refractive layer disposed on the base layer and including titanium and niobium, a first low refractive layer disposed on the first high refractive layer and including silicon, a second high refractive layer disposed on the first low refractive layer, the first high refractive layer and the second high refractive layer including a same material, a second low refractive layer disposed on the second high refractive layer, the first low refractive layer and the second low refractive layer including a same material, an anti-fingerprint layer disposed on the second low refractive layer and including a perfluorinated compound, and a metal layer interposed between the first high refractive layer and the first low refractive layer and including aluminum.

The first high refractive layer may include titanium-niobium oxide, and the first low refractive layer may include silicon oxide.

Each of the first high refractive index layer and the second high refractive index layer may have a refractive index of about 1.7 to about 3.0.

Each of the first low refractive index layer and the second low refractive index layer may have a refractive index of about 1.3 to about 1.6.

The first high refractive layer may include a substitutional solid solution in which a portion of titanium atoms of titanium oxide is replaced by niobium atoms.

The first high refractive layer may include Ti₁₄Nb₃O₃₅, and the first low refractive layer may include SiO2.

A thickness of the metal layer may be about 0.5 nm to 20 nm.

The display apparatus may further include an auxiliary layer interposed between the metal layer and the first low refractive layer, the first high refractive layer and the auxiliary layer including a same material.

According to one or more embodiments, a display apparatus includes a display panel, a cover window disposed on the display panel, and a protective layer disposed on the cover window. The protective layer includes a base layer, a first high refractive layer disposed on the base layer and including titanium and niobium, a first low refractive layer disposed on the first high refractive layer and including silicon, a second high refractive layer disposed on the first low refractive layer, the first high refractive layer and the second high refractive layer including a same material, a second low refractive layer disposed on the second high refractive layer, the first low refractive layer and the second low refractive layer including a same material, an anti-fingerprint layer disposed on the second low refractive layer and including a perfluorinated compound, and a metal layer interposed between the first low refractive layer and the second high refractive layer and including aluminum.

The display apparatus may further include an auxiliary layer interposed between the metal layer and the first low refractive layer, the first high refractive layer and the auxiliary layer including a same material.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display apparatus according to an embodiment.

FIG. 2 is a schematic side view of a display apparatus according to an embodiment.

FIG. 3 is a schematic cross-sectional view of the display apparatus of FIG. 1 taken along line I-I′.

FIG. 4 is a schematic plan view of a display panel included in the display apparatus of FIG. 3.

FIG. 5 is an equivalent circuit diagram of one pixel circuit included in the display panel of FIG. 4.

FIG. 6 is a schematic cross-sectional view of the display panel of FIG. 4 taken along line II-II′.

FIG. 7 is a schematic cross-sectional view of a protective layer included in the display apparatus of FIG. 3.

FIG. 8 is a graph showing a reflectivity of a protective layer according to an embodiment versus a wavelength.

FIG. 9 is a schematic cross-sectional view of a protective layer included in a display apparatus according to an embodiment.

FIG. 10 is a schematic cross-sectional view of a protective layer included in a display apparatus according to an embodiment.

FIG. 11 is a schematic cross-sectional view of a protective layer included in a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

In the present specification, “A and/or B” represents A or B, or A and B. The expression “at least one of A and B” indicates only A, only B, both A and B, or variations thereof.

It will be understood that, unless otherwise specified, when an element such as a layer, film, region or substrate is referred to as being “on” another element, it can be “directly” on the other element or intervening elements may also be present.

When a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

One or more embodiments of the disclosure will be described below in more detail with reference to the accompanying drawings. Those components that are the same as or are in correspondence with each other are rendered the same reference numeral regardless of the figure number, and redundant explanations are omitted. In the drawings, the thicknesses of layers and regions are exaggerated or reduced for convenience of explanation. For example, since sizes and thicknesses of components in the drawings are arbitrarily illustrated for convenience of explanation, embodiments are not limited thereto.

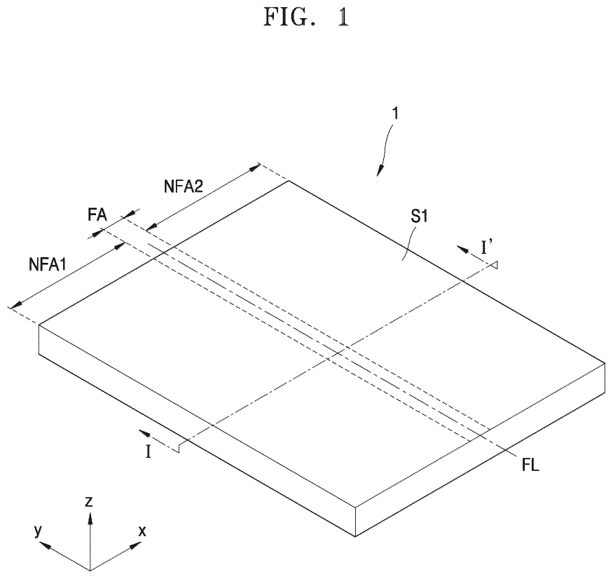

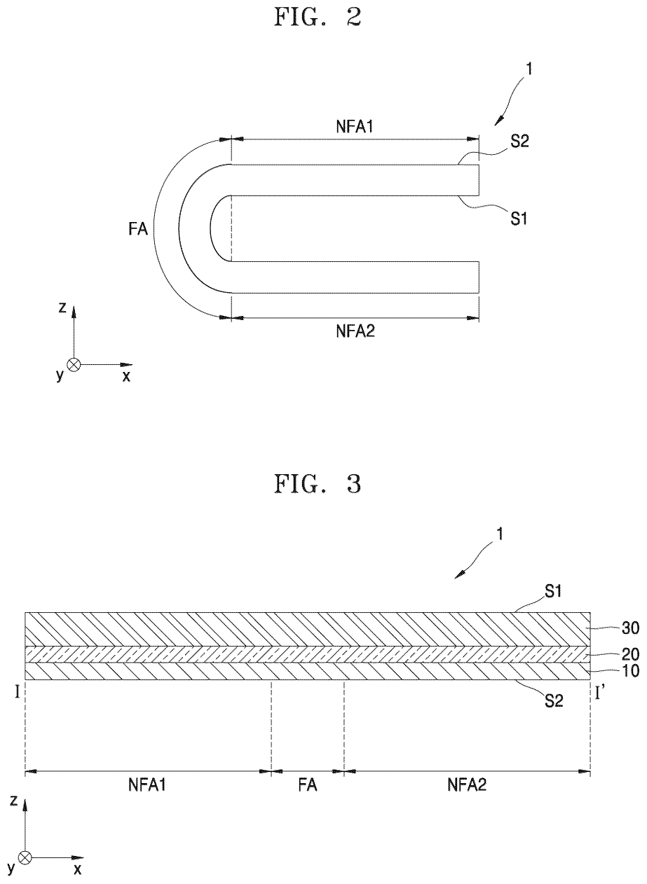

FIG. 1 is a schematic perspective view of a display apparatus 1 according to an embodiment. FIG. 2 is a schematic side view of the display apparatus 1 according to an embodiment. In detail, FIG. 1 shows the display apparatus 1 in an unfolded state, and FIG. 2 shows the display apparatus 1 in a folded state. It may be understood that an x-axis direction refers to a horizontal direction of the display apparatus 1, a y-axis direction refers to a vertical direction of the display apparatus 1, and a z-axis direction refers to a thickness direction of the display apparatus 1. For convenience of description, hereinafter, when referring to surfaces of the display apparatus 1 or each element constituting the display apparatus 1, one surface in a direction in which the display apparatus 1 provides an image (for example, in a +z direction based on FIG. 1) is referred to as an upper surface, and a surface that is opposite to the one surface is referred to as a lower surface. However, the disclosure is not limited thereto. The one surface of the display apparatus 1 or each element constituting the display apparatus 1 and the surface opposite to the one surface may be referred to as a first surface and a second surface, respectively.

Referring to FIGS. 1 and 2, the display apparatus 1 displays a moving image and/or a still image. The display apparatus 1 may refer to any electronic device that provides a display screen. Examples of the display apparatus 1 may include a television, a notebook computer, a monitor, a billboard, the Internet of things, a mobile phone, a smartphone, a tablet personal computer (PC), a digital watch, a smartwatch, a watch phone, a head-mounted display, a mobile communication terminal, an electronic notebook, an e-book, a portable multimedia player (PMP), a navigation device, a game console, a digital camera, and a camcorder, which provide display screens.

The display apparatus 1 may have a polygonal shape including a quadrangle. For example, the display apparatus 1 may have a rectangular shape in which a horizontal length is less than a vertical length, a rectangular shape in which a horizontal length is greater than a vertical length, or a square shape. In an embodiment, the display apparatus 1 may have any of various shapes such as an oval or a circle. Although the display apparatus 1 is illustrated in FIG. 1 as having a rectangular shape in which a horizontal length is less than a vertical length, the disclosure is not limited thereto.

The display apparatus 1 may include a first surface S1 and a second surface S2 that is opposite to the first surface S1. According to an embodiment, the first surface S1 may be an upper surface (in the +z direction) of the display apparatus 1. The second surface S2 may be a lower surface (in a −z direction) of the display apparatus 1. The display apparatus 1 may display an image on the first surface S1. In other words, the first surface S1 may include a display surface. According to an embodiment, the display apparatus 1 may also display an image on the second surface S2.

The display apparatus 1 is foldable. In other words, at least a portion of the display apparatus 1 may have flexibility, and the display apparatus 1 may be folded as the portion having flexibility is bent. Accordingly, the display apparatus 1 may include a folded area and a non-folded area that is arranged on at least one side of the folded area and is not folded. The expression “non-folded” used herein means that a portion is not folded, and covers not only a case where a portion is hard with no flexibility and thus is not folded, but also a case where a portion has flexibility but is not folded. The display apparatus 1 may display an image not only in the non-folded area but also in the folded area.

Referring to FIG. 1, the display apparatus 1 may include a first non-folding area NFA1, a second non-folding area NFA2, and a foldable area FA. The first non-folding area NFA1 and the second non-folding area NFA2 may be non-folded areas, and the foldable area FA may have flexibility and may be a foldable area.

The foldable area FA may extend in a direction intersecting a virtual straight line that connects the first non-folding area NFA1 to the second non-folding area NFA2. In detail, when the display apparatus 1 is unfolded, the first non-folding area NFA1 and the second non-folding area NFA2 may be apart from each other in a first direction (e.g., the x-axis direction). The foldable area FA may be arranged between the first non-folding area NFA1 and the second non-folding area NFA2. In detail, the first non-folding area NFA1 may be adjacent to one side of the foldable area FA, and the second non-folding area NFA2 may be adjacent to the other side of the foldable area FA. When the display apparatus 1 is unfolded, the foldable area FA may extend in a second direction (e.g., the y-axis direction) intersecting the first direction.

A folding line FL may be provided in the foldable area FA in the second direction (e.g., the y-axis direction) in which the foldable area FA extends. Accordingly, the display apparatus 1 may be folded in the foldable area FA. The foldable area FA and the folding line FL of the foldable area FA may overlap a portion of the display apparatus 1 where an image is displayed, and, when the display apparatus 1 is folded, the portion where an image is displayed may be folded.

Although the first non-folding area NFA1 and the second non-folding area NFA2 have the same area or similar areas and the display apparatus 1 includes one foldable area FA in FIG. 1 for convenience of description, one or more embodiments are not limited thereto. For example, the first non-folding area NFA1 and the second non-folding area NFA2 may have different areas from each other. In addition, the display apparatus 1 may include a plurality of foldable areas FA. In this case, a plurality of non-folding areas may be apart from each other, and each of the plurality of foldable areas FA may be arranged between the non-folding areas. Each foldable area FA may be folded along the folding line FL, and a plurality of folding lines FL may be provided.

Although the folding line FL passes through the center of the foldable area FA and the foldable area FA is line-symmetric with respect to the folding line FL in FIG. 1, one or more embodiments are not limited thereto. For example, the folding line FL may be asymmetrically provided in the foldable area FA.

As shown in FIG. 2, the display apparatus 1 may be folded along the folding line FL such that the first surface S1 of the first non-folding area NFA1 and the first surface S1 of the second non-folding area NFA2 may face each other. In other words, as the foldable area FA of the display apparatus 1 is bent, the first surface S1 of the first non-folding area NFA1 and the first surface S1 of the second non-folding area NFA2 may be arranged to face each other. Even when the display apparatus 1 is folded, the foldable area FA may extend in a direction intersecting a virtual straight line that connects the first non-folding area NFA1 to the second non-folding area NFA2. In detail, when the display apparatus 1 is folded, the foldable area FA may extend in the second direction (e.g., the y-axis direction) intersecting a virtual straight line (e.g., a straight line parallel to the z-axis direction) that connects the first non-folding area NFA1 to the second non-folding area NFA2.

The foldable area FA may be bent and then may be unfolded again. That is, the display apparatus 1 may be a foldable display apparatus. The expression “folded” used herein means that a portion is not fixed in shape but is transformed from an original shape to another shape, and may be folded, curved, or bent along at least one specific line, such as the folding line FL. Accordingly, although FIG. 2 shows that the display apparatus 1 is folded such that the first surface S1 of the first non-folding area NFA1 and the first surface S1 of the second non-folding area NFA2 are parallel to each other and face each other in up and down opposite directions, the disclosure is not limited thereto. For example, the display apparatus 1 may be folded such that the first surface S1 of the first non-folding area NFA1 and the first surface S1 of the second non-folding area NFA2 may form a certain angle (e.g., an acute angle, a right angle, and/or an obtuse angle) with the foldable area FA therebetween.

In addition, although FIG. 2 shows that the display apparatus 1 is folded such that the first surface S1 of the first non-folding area NFA1 and the first surface S1 of the second non-folding area NFA2 face each other, that is, is in-folded, the disclosure is not limited thereto. For example, the display apparatus 1 may be folded such that the second surface S2 of the first non-folding area NFA1 and the second surface S2 of the second non-folding area NFA2 may face each other, that is, is out-folded. In other words, the display apparatus 1 may be of an in-folding type in which portions of a display surface face each other when the display apparatus 1 is folded, or may be of an out-folding type in which a display surface is exposed to the outside when the display apparatus 1 is folded. For convenience of description, a case where the display apparatus 1 is of an in-folding type will now be focused on and described in detail.

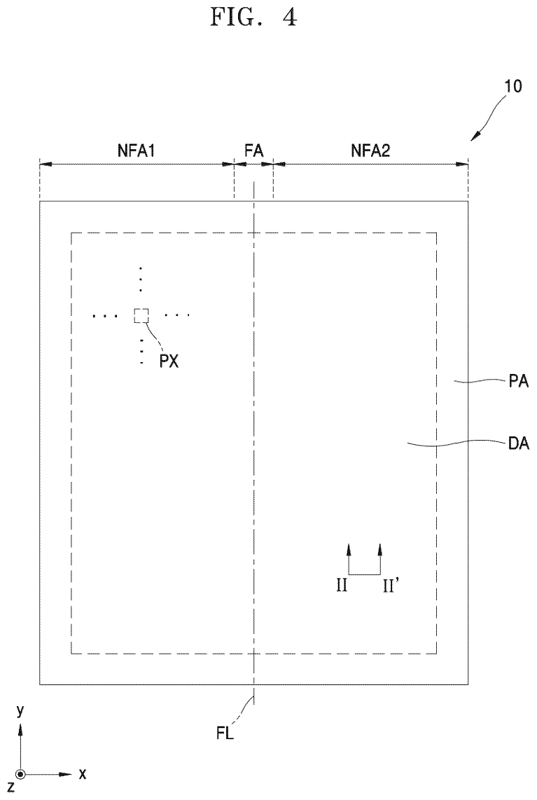

FIG. 3 is a schematic cross-sectional view of the display apparatus 1 of FIG. 1 taken along line I-I′. FIG. 4 is a schematic plan view of a display panel 10 included in the display apparatus 1 of FIG. 3. As shown in FIG. 3, the display apparatus 1 may include the display panel 10, a cover window 20, and a protective layer 30. In some cases, the display apparatus 1 may further include various other elements than the elements shown in FIG. 3.

The display panel 10 may display an image. That is, an image provided by the display apparatus 1 may be understood as being implemented by the display panel 10. To this end, the display panel 10 may include a plurality of display elements, and the plurality of display elements may emit red, green, and/or blue light. Accordingly, the display panel 10 may display an image through light emitted from the plurality of display elements.

According to an embodiment, the display element may be an organic light-emitting diode including an organic emission layer. In an embodiment, the display element may be a light-emitting diode (LED). The size of the LED may be microscale or nanoscale. For example, the LED may be a micro light-emitting diode. As another example, the LED may be a nanorod LED. The nanorod LED may include gallium nitride (GaN). According to an embodiment, a color-converting layer may be arranged on the nanorod LED. The color-converting layer may include quantum dots. In an embodiment, the display element may be a quantum dot light-emitting diode including a quantum dot emission layer. In an embodiment, the display element may be an inorganic light-emitting diode including an inorganic semiconductor. Elements included in the display panel 10 will be described later in more detail.

As described above, the display apparatus 1 may include the first non-folding area NFA1, the second non-folding area NFA2, and the foldable area FA. Because the display apparatus 1 includes the display panel 10, it may be considered that the display panel 10 may include the first non-folding area NFA1, the second non-folding area NFA2, and the foldable area FA as described above. For convenience of explanation, the display panel 10 will now be described as having the first non-folding area NFA1, the second non-folding area NFA2, and the foldable area FA.

In other words, when the display panel 10 is unfolded, the first non-folding area NFA1 and the second non-folding area NFA2 may be apart from each other in the first direction (e.g., the x-axis direction). The foldable area FA may be arranged between the first non-folding area NFA1 and the second non-folding area NFA2, and may extend in a direction intersecting a virtual straight line that connects the first non-folding area NFA1 to the second non-folding area NFA2. The folding line FL may be provided in the foldable area FA in the second direction (e.g., the y-axis direction) in which the foldable area FA extends. Accordingly, the display panel 10 may be folded in the foldable area FA.

As shown in FIG. 4, the display panel 1 may include a display area DA in which a plurality of pixels PX are arranged, and a peripheral area PA located outside the display area DA.

Each of the pixels PX of the display panel 10 is an area capable of emitting light of a certain color, and the display panel 10 may provide an image by using light emitted by the pixels PX. For example, each of the pixels PX may emit red light, green light, and/or blue light. That is, one display element may correspond to one pixel.

The display area DA, which is an area that provides an image, may have a polygonal shape including a quadrangle, as shown in FIG. 4. For example, the display area DA may have a rectangular shape in which a horizontal length is greater than a vertical length, a rectangular shape in which a horizontal length is less than a vertical length, or a square shape. In an embodiment, the display area DA may have any of various shapes such as an oval or a circle.

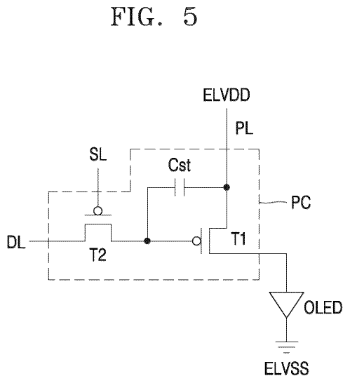

The peripheral area PA is a non-display area that provides no images, and may surround the entirety of the display area DA. In detail, pixels PX are not arranged in the peripheral area PA, and a driver or the like for providing an electrical signal or power to the pixels PX may be arranged in the peripheral area PA. Pads (not shown) may be arranged in the peripheral area PA, and an electronic device or a printed circuit board may be electrically connected to the pads. Each of the pads may be apart from another in the peripheral area PA, and may be electrically connected to a plurality of connection wires arranged in the peripheral area PA. The connection wires may electrically connect signal lines arranged in the display area DA, for example, data lines DL of FIG. 5 (or scan lines SL of FIG. 5), to the pads.

The cover window 20 may be arranged on the display panel 10. In detail, the cover window 20 may be disposed on an upper surface of the display panel 10. According to an embodiment, the cover window 20 may be arranged to cover the upper surface of the display panel 10. An image displayed by the display panel 10 may be provided to a user through the cover window 20 having transparency.

The cover window 20 may protect the upper surface of the display panel 10. The cover window 20 may have high strength and hardness to protect the display panel 10 from external impacts. The cover window 20 may have a high transmittance to transmit light emitted by the display panel 10, and may have a small thickness to minimize the weight of the display apparatus 1. Because the cover window 20 forms the exterior of the display apparatus 1, the cover window 20 may include a flat surface and a curved surface corresponding to the shape of the display apparatus 1.

The cover window 20 may be a flexible window. The cover window 20 may protect the display panel 10 while being easily bent along an external force without generating cracks or the like. The cover window 20 may include glass or plastic. According to an embodiment, the cover window 20 may include ultra-thin tempered glass (ultra-thin glass, UTG®) having a strength enhanced by a method such as chemical strengthening or thermal strengthening. According to an embodiment, the cover window 20 may include polymer resin.

Although not shown, an adhesive member may be disposed between the display panel 10 and the cover window 20. The adhesive member may include at least one of an optical clear resin (OCR), an optical clear adhesive (OCA), and a pressure sensitive adhesive (PSA). The adhesive member may couple the display panel 10 and the cover window 20 to each other.

The protective layer 30 may be disposed on the cover window 20. The protective layer 30 may protect the cover window 20 and may prevent or reduce the occurrence of scratches on an upper surface of the cover window 20. The protective layer 30 may include a plurality of sub-layers. According to an embodiment, the protective layer 30 may include an organic layer. For example, the protective layer 30 may include an acryl-based polymer. When the protective layer 30 includes an organic layer, the protective layer 30 may have improved flexibility. According to an embodiment, the protective layer 30 may further include an inorganic layer. A structure of the protective layer 30 and a material included in the protective layer 30 will be described below in more detail.

Although not shown, an adhesive member may be disposed between the cover window 20 and the protective layer 30. The adhesive member may include at least one of an OCR, an OCA, and a PSA. The adhesive member may couple the cover window 20 and the protective layer 30 to each other.

FIG. 5 is an equivalent circuit diagram of a pixel circuit PC included in the display panel 10 of FIG. 4. The pixel circuit PC may be electrically connected to a display element, and one display element may correspond to one pixel. In FIG. 5, an organic light-emitting diode OLED is shown as a display element. According to an embodiment, the display element may emit red light, green light, or blue light.

The pixel circuit PC may include a first transistor T1, a second transistor T2, and a storage capacitor Cst. The second transistor T2, which is a switching transistor, may be connected to a scan line SL and a data line DL, and may be turned on by a switching signal received from the scan line SL to transmit, to the first transistor T1, a data signal received from the data line DL. The storage capacitor Cst may have one end electrically connected to the second transistor T2 and the other end electrically connected to a driving voltage line PL, and may store a voltage corresponding to a difference between a voltage received from the second transistor T2 and a driving power supply voltage ELVDD supplied to the driving voltage line PL.

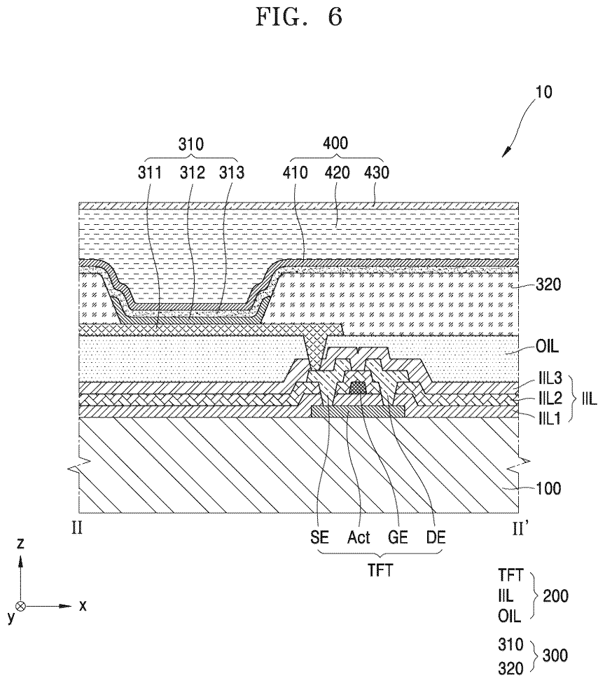

The first transistor T1, which is a driving transistor, may be connected to the driving voltage line PL and the storage capacitor Cst, and may be configured to control the magnitude of a driving current flowing from the driving voltage line PL to the organic light-emitting diode OLED, in accordance with a voltage value stored in the storage capacitor Cst. The organic light-emitting diode OLED may emit light having a certain brightness due to the driving current. An opposite electrode 313 (see FIG. 6) of the organic light-emitting diode OLED may receive an electrode power supply voltage ELVSS.

Although FIG. 5 illustrates that the pixel circuit PC includes two transistors T1, T2 and one storage capacitor Cst, the disclosure is not limited thereto. For example, the number of transistors or the number of storage capacitors may vary according to a design of the pixel circuit PC.

FIG. 6 is a schematic cross-sectional view of the display panel 10 of FIG. 4 taken along line II-II′. Referring to FIG. 6, the display panel 10 may include a substrate 100, a pixel circuit layer 200, a display element layer 300, and an encapsulation layer 400.

The substrate 100 may include glass, a metal, or a polymer resin. The substrate 100 needs to have flexible or bendable characteristics. In this case, the substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including a polymer resin and a barrier layer including an inorganic material (silicon oxide (SiO_{X}), silicon nitride (SiN_{X}), silicon oxynitride (SiO_{X}N_{Y}), or the like) and located between the two layers. In this way, various modifications may be made.

The pixel circuit layer 200 may be disposed on the substrate 100. The pixel circuit layer 200 may include a thin-film transistor TFT, an inorganic insulating layer IIL, and an organic insulating layer OIL. The thin-film transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, one thin-film transistor TFT is shown in FIG. 6, and the thin-film transistor TFT may correspond to the above-described first transistor (driving transistor) T1 of FIG. 5.

The semiconductor layer Act may be arranged on the substrate 100. The semiconductor layer Act may include polysilicon. In an embodiment, the semiconductor layer Act may include amorphous silicon, an oxide semiconductor, or an organic semiconductor. According to an embodiment, the semiconductor layer Act may include a channel region, and a source region and a drain region respectively arranged on both sides of the channel region.

The gate insulating layer IIL1 may be disposed on the semiconductor layer Act and the substrate 100. The gate insulating layer IIL1 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}). The zinc oxide (ZnO_{X}) may include a zinc oxide (ZnO) and/or a zinc peroxide (ZnO₂).

The gate electrode GE may be disposed on the gate insulating layer IIL1. That is, the gate insulating layer IIL1 may be disposed between the semiconductor layer Act and the gate electrode GE to provide insulation between the semiconductor layer Act and the gate electrode GE. The gate electrode GE may overlap the channel region of the semiconductor layer Act. The gate electrode GE may include a low resistance metal material. According to an embodiment, the gate electrode GE may include a conductive material including molybdenum (Mo), aluminum (AI), copper (Cu), and titanium (Ti), and may have a single-layer or multi-layer structure including the aforementioned conductive materials.

The first interlayer insulating layer IIL2 may be disposed on the gate electrode GE and the gate insulating layer IIL1. The first interlayer insulating layer IIL2 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}).

The source electrode SE and the drain electrode DE may be arranged on the first interlayer insulating layer IIL2. The source electrode SE and the drain electrode DE may each be connected to the semiconductor layer Act via a contact holes formed in the gate insulating layer IIL1 and the first interlayer insulating layer IIL2. At least one of the source electrode SE and the drain electrode DE may include a conductive material including, for example, molybdenum (Mo), aluminum (AI), copper (Cu), or titanium (Ti), and may have a multi-layer or single-layer structure including the aforementioned conductive materials. According to an embodiment, at least one of the source electrode SE and the drain electrode DE may have a multi-layer structure of Ti/Al/Ti.

The second interlayer insulating layer IIL3 may be disposed on the source electrode SE, the drain electrode DE, and the first interlayer insulating layer IIL2. The second interlayer insulating layer IIL3 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}).

The organic insulating layer OIL may be arranged on the second interlayer insulating layer IIL3. The organic insulating layer OIL may substantially planarize the top of the pixel circuit layer 200. The organic insulating layer OIL may include an organic material, such as acryl, benzocyclobutene (BCB) or hexamethyldisiloxane (HMDSO). Although the organic insulating layer OIL is a single layer in FIG. 6, various modifications may be made to the organic insulating layer OIL. For example, the organic insulating layer OIL may be a stack of multiple layers.

The display element layer 300 may be disposed on the pixel circuit layer 200. The display element layer 300 may include a display element 310 and a pixel defining layer 320. The display element 310 may be electrically connected to the thin-film transistor TFT. The display element 310 may be, for example, an organic light-emitting diode having a pixel electrode 311, the opposite electrode 313, and an intermediate layer 312 between the pixel electrode 311 and the opposite electrode 313 and including an emission layer. The display element 310 being electrically connected to the thin-film transistor TFT may be understood as the pixel electrode 311 of the organic light-emitting diode being electrically connected to the thin-film transistor TFT.

The pixel electrode 311 may contact one of the source electrode SE and the drain electrode DE through a contact hole formed in the second interlayer insulating layer IIL3 and the organic insulating layer OIL, and may be electrically connected to the thin-film transistor TFT. The pixel electrode 311 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). According to an embodiment, the pixel electrode 311 may include a reflective layer including, for example, silver (Ag), magnesium (Mg), aluminum (AI), platinum (Pt), palladium (Pd), gold (Au), nickel (Ni), neodymium (Nd), iridium (Ir), chromium (Cr), or a compound of these materials. According to an embodiment, the pixel electrode 311 may further include a film formed of ITO, IZO, ZnO, or In₂O₃ over/under the reflective layer.

A pixel-defining layer 320 may cover an edge of the pixel electrode 311. The pixel-defining layer 320 may include a pixel opening, and the pixel opening may overlap the pixel electrode 311. The pixel opening may define an emission area of light emitted by the display element 310. The pixel-defining layer 320 may include an organic insulating material and/or an inorganic insulating material. According to some embodiments, the pixel-defining layer 320 may include a light-blocking material.

The intermediate layer 312 may be disposed on the pixel electrode 311 and the pixel-defining layer 320. The intermediate layer 312 may include a low-molecular weight or high-molecular weight material. When the intermediate layer 312 includes a low-molecular weight material, the intermediate layer 312 may have a single- or multi-layered stack structure including at least one of a hole injection layer (HIL), a hole transport layer (HTL), an emission layer (EML), an electron transport layer (ETL) and an electron injection layer (EIL), and may be formed via vacuum deposition. When the intermediate layer 312 includes a high-molecular weight material, the intermediate layer 312 may have a structure including an HTL and an EML. In this case, the HTL may include poly(ethylenedioxythiophene) (PEDOT), and the EML may include a high-molecular weight material such as a polyphenylene vinylene (PPV)-based material or a polyfluorene-based material. The intermediate layer 312 may be formed via screen printing, inkjet printing, laser induced thermal imaging (LITI), or the like. However, the intermediate layer 312 is not limited thereto, and may have any of various other structures. The intermediate layer 312 may include a single layer that covers a plurality of pixel electrodes 311 or may include patterned layers respectively corresponding to the plurality of pixel electrodes 311.

The opposite electrode 313 may be disposed on the intermediate layer 312 and the pixel-defining layer 320. The opposite electrode 313 may be integrally formed over a plurality of organic light-emitting diodes, and thus may correspond to the plurality of pixel electrodes 311. The opposite electrode 313 may include a light-transmissive conductive layer formed of ITO, In₂O₃, or IZO, and also include a semi-transmissive layer including a metal such as Al or Ag. For example, the opposite electrode 313 may be a semi-transmissive layer including Mg or Ag.

Because the display element 310 may be easily damaged by external moisture, oxygen, or the like, the encapsulation layer 400 may cover and protect the display element 310. As illustrated in FIG. 6, the encapsulation layer 400 may include a first inorganic encapsulation layer 410, an organic encapsulation layer 420, and a second inorganic encapsulation layer 430.

In an embodiment, the first inorganic encapsulation layer 410 may cover the opposite electrode 313 and may include silicon oxide (SiO_{X}), silicon nitride (SiN_{X}) and/or silicon oxynitride (SiO_{X}N_{Y}). As necessary, other layers, such as, a capping layer, may be interposed between the first inorganic encapsulation layer 410 and the opposite electrode 313. Because the first inorganic encapsulation layer 410 is formed along structures below the first inorganic encapsulation layer 410, the upper surface thereof may not be flat, as shown in FIG. 6. The organic encapsulation layer 420 covers the first inorganic encapsulation layer 410. In contrast with the first inorganic encapsulation layer 410, the organic encapsulation layer 420 may have an approximately flat upper surface. The organic encapsulation layer 420 may include at least one material from among polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420, and may include silicon oxide (SiO_{X}), silicon nitride (SiN_{X}) and/or silicon oxynitride (SiO_{X}N_{Y}).

As such, the encapsulation layer 400 includes the first inorganic encapsulation layer 410, the organic encapsulation layer 420, and the second inorganic encapsulation layer 430, and thus, even when the encapsulation layer 400 cracks due to this multi-layered structure, these cracks may not be connected between the first inorganic encapsulation layer 410 and the organic encapsulation layer 420 or between the organic encapsulation layer 420 and the second inorganic encapsulation layer 430. Accordingly, formation of a path via which external moisture, oxygen, or the like permeates into the display panel 10 may be prevented or minimized.

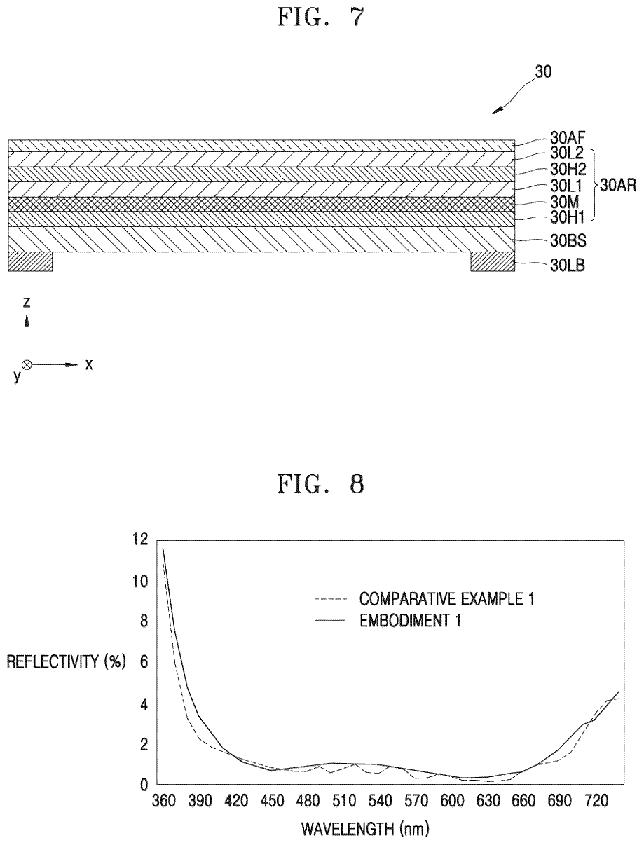

FIG. 7 is a schematic cross-sectional view of the protective layer 30 included in the display apparatus 1 of FIG. 3. As shown in FIG. 7, the protective layer 30 may include a base layer 30BS, an anti-reflection layer 30AR, an anti-fingerprint layer 30AF, and a light-shielding layer 30LB.

The base layer 30BS may be disposed on the cover window 20. The base layer 30BS may be a plastic film including polymer resin. For example, the base layer 30BS may include at least one of polymer resins, such as polyethylene terephthalate (PET), poly(butylene terephthalate) (PBT), polycarbonate (PC), polyethylene naphthalate (PEN), polystyrene (PS), polymethyl methacrylate (PMMA), polyvinylchloride (PVC), polyethersulfone (PES), polypropylene (PP), and/or polyamide (PA).

The anti-reflection layer 30AR may be disposed on the base layer 30BS. The anti-reflection layer 30AR may reduce the reflectivity of externally incident light. The anti-reflection layer 30AR may have a stacked structure including a plurality of sub-layers. In detail, the anti-reflection layer 30AR may include a first high refractive layer 30H1, a first low refractive layer 30L1, a second high refractive layer 30H2, a second low refractive layer 30L2, and a metal layer 30M.

The first high refractive layer 30H1 may be disposed on the base layer 30BS. The first high refractive layer 30H1 may include a high-refractive material. The first high refractive layer 30H1 may include oxide, and the first high refractive layer 30H1 may include titanium (Ti) and niobium (Nb). According to an embodiment, the first high refractive layer 30H1 may include titanium-niobium oxide. For example, the titanium-niobium oxide may be Ti₁₄Nb₃O₃₅, and the titanium-niobium oxide may be provided as a substitutional solid solution. That is, the titanium-niobium oxide may be provided as a substitutional solid solution, in which a portion of titanium atoms of titanium oxide is replaced by niobium atoms. In other words, the first high refractive layer 30H1 may include a substitutional solid solution, in which a portion of titanium atoms of titanium oxide is replaced by niobium atoms.

According to an embodiment, a refractive index of the first high refractive layer 30H1 may be in the range of about 1.7 to about 3. In detail, a refractive index of the first high refractive layer 30H1 with respect to a wavelength of 550 nanometers (nm) may be about 2.17.

The first low refractive layer 30L1 may be disposed on the first high refractive layer 30H1. The first low refractive layer 30L1 may include a low-refractive material. The first low refractive layer 30L1 may include oxide, and the first low refractive layer 30L1 may include silicon (Si). According to an embodiment, the first low refractive layer 30L1 may include silicon oxide. For example, the silicon oxide may be SiO2.

According to an embodiment, a refractive index of the first low refractive layer 30L1 may be less than the refractive index of the first high refractive layer 30H1. The refractive index of the first low refractive layer 30L1 may be in the range of about 1.4 to about 1.6. In detail, a refractive index of the first low refractive layer 30L1 with respect to a wavelength of 550 nm may be about 1.46.

The second high refractive layer 30H2 may be disposed on the first low refractive layer 30L1. The second high refractive layer 30H2 may include a high-refractive material. The second high refractive layer 30H2 may include the same material as the material included in the first high refractive layer 30H1. In detail, the second high refractive layer 30H2 may include oxide, and the second high refractive layer 30H2 may include titanium (Ti) and niobium (Nb). According to an embodiment, the second high refractive layer 30H2 may include titanium-niobium oxide. For example, the titanium-niobium oxide may be Ti₁₄Nb₃O₃₅, and the titanium-niobium oxide may be provided as a substitutional solid solution. That is, the titanium-niobium oxide may be provided as a substitutional solid solution, in which a portion of titanium atoms of titanium oxide is replaced by niobium atoms. In other words, the second high refractive layer 30H2 may include a substitutional solid solution, in which a portion of titanium atoms of titanium oxide is replaced by niobium atoms.

According to an embodiment, a refractive index of the second high refractive layer 30H2 may be the same as or similar to the refractive index of the first high refractive layer 30H1. The refractive index of the second high refractive layer 30H2 may be in the range of about 1.7 to about 3. In detail, a refractive index of the second high refractive layer 30H2 with respect to a wavelength of 550 nm may be about 2.17. That is, each of the first high refractive layer 30H1 and the second high refractive layer 30H2 may have a refractive index of about 1.7 to about 3.0.

The second low refractive layer 30L2 may be disposed on the second high refractive layer 30H2. The second low refractive layer 30L2 may include a low-refractive material. The second low refractive layer 30L2 may include the same material as the material included in the first low refractive layer 30L1. In detail, the second low refractive layer 30L2 may include oxide, and the second low refractive layer 30L2 may include silicon (Si). According to an embodiment, the second low refractive layer 30L2 may include silicon oxide. For example, the silicon oxide may be SiO2.

According to an embodiment, a refractive index of the second low refractive layer 30L2 may be the same as or similar to the refractive index of the first low refractive layer 30L1. The refractive index of the second low refractive layer 30L2 may be in the range of about 1.4 to about 1.6. In detail, a refractive index of the first low refractive layer 30L1 with respect to a wavelength of 550 nm may be about 1.46. That is, each of the first low refractive layer 30L1 and the second low refractive layer 30L2 may have a refractive index of about 1.4 to about 1.6.

That is, the anti-reflection layer 30AR may have a structure in which high refractive layers including titanium-niobium oxide provided as a substitutional solid solution and low refractive layers including silicon oxide provided as a substitutional solid solution are alternately stacked. By adjusting a thickness and a refractive index of each of the high refractive layers and the low refractive layers, lights reflected by interfaces between the respective layers (e.g., a high refractive layer and a low refractive layer) destructively interfere with each other, and thus, the anti-reflection layer 30AR may reduce the reflectivity of externally incident light.

In general, oxide including a plurality of kinds of elements, such as titanium-niobium oxide, may be provided as a substitutional solid solution, an interstitial solid solution, or a simple mixture. A solid solution refers to a solid mixture that forms a completely uniform phase. A substitutional solid solution is a form in which solute atoms are substituted for the original solvent atoms, so that the solute atoms are placed at the positions of the original solvent atoms. An interstitial solid solution is a form in which the solute atoms are placed in the spaces between the original solvent atoms. A simple mixture is a form in which a plurality of types of elements each form oxides and such a plurality of types of oxides are mixed. For example, the simple mixture may be a mixed form of TiO_{X} (e.g., TiO₂) and NbO_{X} (e.g., NbO₃).

The substitutional solid solution may be more stable because bonds are formed between neighboring solute atoms and solvent atoms, and may have improved attaching force because of having a high-density structure. In the present embodiment, the first high refractive layer 30H1 and the second high refractive layer 30H2 may be provided as substitutional solid solutions. Accordingly, the substitutional solid solution may be more stable because bonds are formed between neighboring solute atoms and solvent atoms, and may have improved attaching force because of having a high-density structure. Thus, even when the display apparatus 1 is folded, cracks may not occur in the anti-reflection layer 30AR or the occurrence of cracks may be effectively reduced.

The high refractive layers including titanium-niobium oxide provided as a substitutional solid solution may be formed on the base layer 30BS at low temperature by ion-assisted deposition (IAD). When IAD is utilized and deposition particles of high-refractive materials are attached to the baser layer 30BS, ionized argons, oxygens, or the like may collide together, thereby increasing kinetic energy of the deposition particles. Accordingly, bonding force (or adhesive force or attaching force) of a deposited layer may be increased.

In addition, silicon oxide has a high bonding force (or adhesive force or attaching force) with other materials. Accordingly, the low refractive layer may improve bonding force (or adhesive force or attaching force) between the high refractive layers. That is, the first low refractive layer 30L1 may be disposed between the first high refractive layer 30H1 and the second high refractive layer 30H2 to improve adhesion between the first high refractive layer 30H1 and the second high refractive layer 30H2, thereby preventing or reducing detachment of the second high refractive layer 30H2 from the first high refractive layer 30H1.

The metal layer 30M may be disposed between a high refractive layer included in the anti-reflection layer 30AR and a low refractive layer placed above or below the high refractive index layer. According to an embodiment, the metal layer 30M may be interposed between the first high refractive layer 30H1 and the first low refractive layer 30L1. The metal layer 30M may include a highly flexible material. For example, the metal layer 30M may include aluminum (Al).

Because aluminum has high flexibility, when the strain of an object made of aluminum according to stress applied to the object, a change in the strain according to a change in stress in a stress-strain curve is continuous. That is, the stress-strain curve of the object made of aluminum may not have a yield point. Accordingly, when the anti-reflection layer 30AR includes the metal layer 30M including aluminum, the flexibility of the anti-reflection layer 30AR increases so that, even when the display apparatus 1 is folded, cracks may not occur in the anti-reflection layer 30AR or occurrence of cracks may be effectively reduced.

A thickness of the metal layer 30M may be 0.5 nm to 20 nm. In detail, the thickness of the metal layer 30M may be 1 nm to 3 nm. That is, the metal layer 30M may be a thin film made of aluminum. When the thickness of the metal layer 30M is less than the aforementioned range, an effect of increasing the flexibility of the anti-reflection layer 30AR is not sufficient, so, even when the anti-reflection layer 30AR includes the metal layer 30M, an effect of reducing the occurrence of cracks may be slight. When the thickness of the metal layer 30M exceeds this range, the reflectivity of the anti-reflection layer 30AR may increase.

The anti-fingerprint layer 30AF may be disposed on the anti-reflection layer 30AR. In detail, the anti-fingerprint layer 30AF may be disposed on the second low refractive layer 30L2. That is, the anti-fingerprint layer 30AF may be located on a surface of the protective layer 30. The anti-fingerprint layer 30AF may suppress abrasion of the surface of the protective layer 30. According to an embodiment, the anti-fingerprint layer 30AF may include a perfluorinated compound. According to an embodiment, the anti-fingerprint layer 30AF may include perfluoropolyether (PFPE). In perfluoropolyether, highly flexible ether bonds are introduced into a hard and short perfluoroalkyl chain. Accordingly, perfluoropolyether may have soft amorphous properties, excellent anti-fingerprint properties, and excellent slip properties. However, the disclosure is not limited thereto.

The anti-fingerprint layer 30AF may be formed, for example, by a method, such as electron-beam (E-beam) vapor deposition, sputtering, thermal deposition, or spin coating. According to an embodiment, the anti-fingerprint layer 30AF may be formed by E-beam vapor deposition.

As described above, silicon oxide has a high bonding force (or adhesive force or attaching force) with other materials. Accordingly, when the anti-fingerprint layer 30AF is directly disposed on the low refractive layer including silicon oxide, bonding force (e.g., adhesive force and/or attaching force) between the low refractive layer and the anti-fingerprint layer 30AF may be high, and thus, the anti-fingerprint layer 30AF may not easily peel off from the anti-reflection layer 30AR.

The light-shielding layer 30LB may be disposed under the base layer 30BS. In detail, the light-shielding layer 30LB may be opposite to the anti-reflection layer 30AR with the baser layer 30BS therebetween. In addition, the light-shielding layer 30LB may be positioned along edges of the protective layer 30. That is, the light-shielding layer 30LB may overlap the peripheral area PA of the display panel 10 described above with reference to FIG. 4. Accordingly, the light-shielding layer 30LB may prevent a wire or circuit located in the peripheral area PA of the display panel 10 from being identified from the outside, and may prevent light leakage of the display panel 10. That is, a region where the light-shielding layer 30LB is arranged may be a bezel area of the display apparatus 1.

The light-shielding layer 30LB may have a single-layer or multi-layer structure, and may include at least one of acrylic urethane, epoxy, polyester, and/or epoxy ester.

Although not shown, the protective layer 30 may further include a hard coating layer (not shown) between the base layer 30BS and the anti-reflection layer 30AR. The hard coating layer may be directly disposed on an upper surface of the base layer 30BS to protect the base layer 30BS. The hard coating layer may be formed from a hard coating layer resin including at least one of an organic-based composition, an inorganic-based composition, and an organic-inorganic composite composition. For example, a hard coating agent used to form the hard coating layer may include at least one of an acrylate-based compound, a siloxane compound, or a silsesquioxane compound. The hard coating agent may further include inorganic particles. Accordingly, the hard coating layer may be an organic layer, an inorganic layer, or an organic-inorganic composite layer.

According to an embodiment, the crack strain of the protective layer 30 may be about 7.0% or greater. The crack strain refers to a level of increase in the size of a test sample before cracks occur in the test sample due to stretching, relative to the size of an initial test sample. For example, the protective layer 30 having the structure described above with reference to FIG. 7 was cut to a preset size. A stretching speed was set to 10 millimeters per minute (mm/min), and after performing stretching, occurrence or non-occurrence of cracks was observed with a microscope, and a level of increase in the size of a test sample at the point was measured. The measured crack strain of the protective layer 30 was about 7%. That is, the size of the protective layer 30 having been stretched increased by about 7% compared to the size of the protective layer 30 before being stretched, but no cracks occurred in the stretched protective layer 30. Accordingly, the protective layer 30 according to the present embodiment satisfies required mechanical properties (e.g., strength or hardness).

According to an embodiment, a contact angle of a surface of the protective layer 30 with respect to water obtained after applying a load of about 1 kg to the surface of the protective layer 30 by using an eraser and performing reciprocating friction 5,000 times over a distance of 15 mm at a speed of 40 cycles/min may be 95 degrees) (° or greater. That is, abrasion resistance evaluation may be performed by measuring a water contact angle after applying a load of about 1 kg to the surface of the protective layer 30 by using an eraser and reciprocating a distance of 15 mm at a speed of 40 cycles/min 5,000 times.

For example, the protective layer 30 having the structure described above with reference to FIG. 7 was cut into a preset size and fixed to a jig of a scratch tester (Daesung Precision Co., Ltd.), and Rubber stick (Minoan Co., Ltd.) having a diameter of 6 mm was mounted at the tip. The Rubber stick was subjected to reciprocating friction on a surface of the protective layer 30 by setting the moving distance as 15 mm, the moving speed as 40 cycles/min, and the load as 1.0 kg, and then, a water contact angle of the worn surface was measured. The contact angle of the surface of the protective layer 30 with respect to water measured in the abrasion resistance evaluation was 95° or greater.

The surface of the protective layer 30 that is antifouling-treated has hydrophobicity, and, when the surface of the protective layer 30 has hydrophobicity, a contact angle with respect to water may increase. However, the surface of the protective layer 30 may be hydrophilized by external repeated stress and/or strong impact, and, when the surface of the protective layer 30 is hydrophilized, a contact angle with respect to water may be reduced.

When the contact angle of the surface of the protective layer 30 with respect to water measured in the abrasion resistance evaluation is 95° or greater, this may mean that the surface of the protective layer 30 withstands external stress and impact well. When the contact angle of the surface of the protective layer 30 with respect to water measured in the abrasion resistance evaluation is less than 95°, this may mean that the surface of the protective layer 30 does not withstand external stress and impact well. Accordingly, when a contact angle of the surface of the protective layer 30 with respect to water measured after performing 5,000 times of reciprocating friction is 95° or greater, this corresponds to a case where the protective layer 30 satisfies required abrasion resistance (SPEC IN). When the contact angle of the surface of the protective layer 30 with respect to water measured after performing 5,000 times of reciprocating friction is less than 95°, this corresponds to a case where the protective layer 30 does not satisfy required abrasion resistance (SPEC OUT). Accordingly, the protective layer 30 according to the present embodiment satisfies required abrasion resistance.

According to an embodiment, a contact angle of a surface of the protective layer 30 with respect to water obtained after providing a chemical on the surface of the protective layer 30, applying a load of about 1 kg to the surface of the protective layer 30 by using an eraser and performing reciprocating friction 3,000 times over a distance of 15 mm at a speed of 40 cycles/min may be 95 degrees) (° or greater. That is, chemical resistance evaluation may be performed by measuring a water contact angle after providing a chemical on the surface of the protective layer 30, applying a load of about 1 kg to the surface of the protective layer 30 by using an eraser and reciprocating a distance of 15 mm at a speed of 40 cycles/min 3,000 times.

For example, the protective layer 30 having the structure described above with reference to FIG. 7 was cut into a preset size and fixed to a jig of a scratch tester (Daesung Precision Co., Ltd.), and Rubber stick (Minoan Co., Ltd.) having a diameter of 6 mm was mounted at the tip. After anhydrous ethanol was sprayed on a surface of the protective layer 30, and then, in the presence of the ethanol, the Rubber stick was subjected to reciprocating friction on the surface of the protective layer 30 by setting the moving distance as 15 mm, the moving speed as 40 cycles/min, and the load as 1.0 kg, the surface of the protective layer 30 was cleaned several times, and a water contact angle of the worn surface was measured. The contact angle of the surface of the protective layer 30 with respect to water measured in the chemical resistance evaluation was 95° or greater.

When a contact angle with respect to water measured in the chemical resistance evaluation is 95° or greater, this may denote that the surface of the protective layer 30 withstands a chemical well. When the contact angle with respect to water measured in the chemical resistance evaluation is less than 95°, this may denote that the surface of the protective layer 30 does not withstand a chemical well. Accordingly, when a contact angle of the surface of the protective layer 30 with respect to water measured after providing a chemical on the surface of the protective layer 30 and performing 3,000 times of reciprocating friction is 95° or greater, this corresponds to a case where the protective layer 30 satisfies required chemical resistance (SPEC IN). When the contact angle of the surface of the protective layer 30 with respect to water measured after providing a chemical on the surface of the protective layer 30 and performing 3,000 times of reciprocating friction is less than 95°, this corresponds to a case where the protective layer 30 does not satisfy required chemical resistance (SPEC OUT). Accordingly, the protective layer 30 according to the present embodiment satisfies required chemical resistance.

According to an embodiment, the reflectivity of the protective layer 30 may be about 1% or less. In detail, the reflectivity of the protective layer 30 may be about 0.6% to about 0.8%. The reflectivity may be measured in a specular component included (SCI) mode. The measured reflectivity of the protective layer 30 was about 0.79%. Accordingly, the protective layer 30 according to the present embodiment satisfies required optical characteristics.

FIG. 8 is a graph showing a reflectivity of the protective layer 30 according to an embodiment versus a wavelength. For convenience of explanation, FIG. 8 also shows a reflectivity of a protective layer according to a comparative example versus a wavelength. In detail, Embodiment 1 is the protective layer 30 including the metal layer 30M, and the thickness of the metal layer 30M is about 2 nm. Comparative Example 1 is a protective layer that does not include the metal layer 30M. Comparative Example 1 differs from Embodiment 1 only in the inclusion of the metal layer 30M, and the other structures are identical.

As illustrated in FIG. 8, the reflectivity of the protective layer 30 including the metal layer 30M is similar to the reflectivity of the protective layer not including the metal layer 30M. In detail, the reflectivity of Embodiment 1 for a wavelength of 550 nm is 0.79%, and the reflectivity of Comparative Example 1 for a wavelength of 550 nm is 0.6%. That is, even when the protective layer 30 includes the metal layer 30M, a degree to which the reflectivity of the protective layer 30 increases accordingly is not large.

Although the metal layer 30M is illustrated as being in direct contact with a low-refractive layer, for example, the first low-refractive layer 30L1 in FIG. 7, the disclosure is not limited thereto. For example, a layer including the same material as the material included in a high refractive layer may be interposed between the metal layer 30M and the first low refractive index layer 30L1.

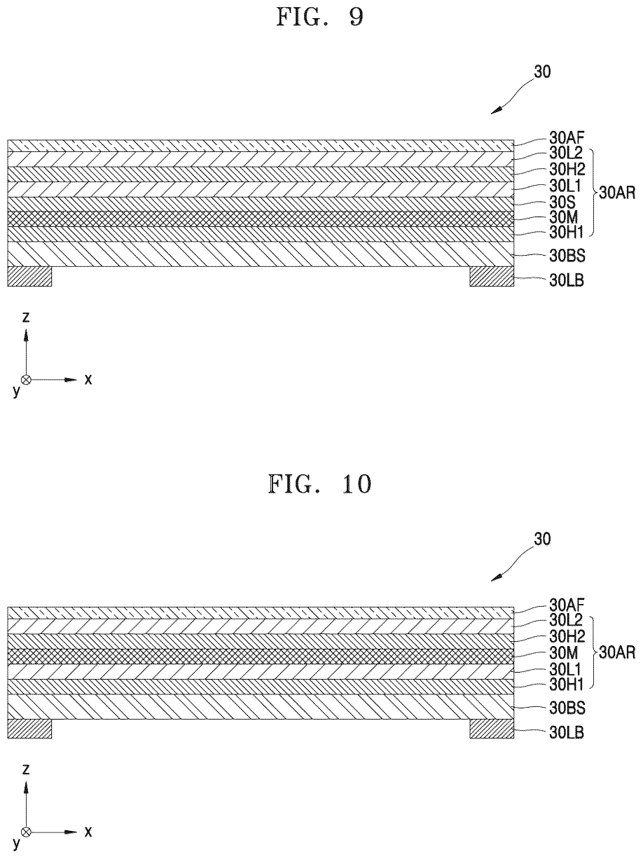

FIG. 9 is a schematic cross-sectional view of a protective layer 30 included in the display apparatus 1 according to an embodiment. Because the protective layer 30 included in the display apparatus 1 according to the present embodiment is similar to the protective layer 30 included in the display apparatus 1 described above with reference to FIG. 7, a difference from the protective layer 30 described above with reference to FIG. 7 will now be focused on and described. Reference numerals in FIG. 9 that are the same as the reference numerals in FIGS. 1 through 7 denote the same elements, and thus repeated descriptions thereof are omitted.

In the case of the protective layer 30 included in the display apparatus 1 according to the embodiment described above with reference to FIG. 7, the protective layer 30 includes the base layer 30BS, the anti-reflection layer 30AR, the anti-fingerprint layer 30AF, and the light-shielding layer 30LB. The anti-reflection layer 30AR includes the first high-refractive layer 30H1, the first low-refractive layer 30L1, the second high-refractive layer 30H2, the second low-refractive layer 30L2, and the metal layer 30M. Even in the case of the protective layer 30 included in the display apparatus 1 according to the present embodiment, the protective layer 30 includes the base layer 30BS, the anti-reflection layer 30AR, the anti-fingerprint layer 30AF, and the light-shielding layer 30LB, and the anti-reflection layer 30AR includes the first high-refractive layer 30H1, the first low-refractive layer 30L1, the second high-refractive layer 30H2, the second low-refractive layer 30L2, and the metal layer 30M.

However, in the protective layer 30 included in the display apparatus 1 according to the present embodiment, the anti-reflection layer 30AR may further include an auxiliary layer 30S. The auxiliary layer 30S may be interposed between the metal layer 30M and a low-refractive layer adjacent to the metal layer 30M. For example, the auxiliary layer 30S may be interposed between the metal layer 30M and the first low-refractive layer 30L1. The auxiliary layer 30S may include a high-refractive material. The auxiliary layer 30S may include the same material as the material included in the first high refractive layer 30H1.

In detail, the auxiliary layer 30S may include oxide, and the auxiliary layer 30S may include titanium (Ti) and niobium (Nb). According to an embodiment, the auxiliary layer 30S may include titanium-niobium oxide. For example, the titanium-niobium oxide may be Ti₁₄Nb₃O₃₅, and the titanium-niobium oxide may be provided as a substitutional solid solution. That is, the titanium-niobium oxide may be provided as a substitutional solid solution, in which a portion of titanium atoms of titanium oxide is replaced by niobium atoms. In other words, the auxiliary layer 30S may include a substitutional solid solution, in which a portion of titanium atoms of titanium oxide is replaced by niobium atoms. Because the auxiliary layer 30S includes the same material as the material included in a high refractive layer, the auxiliary layer 30S may perform at least part of the role of the high refractive layer. Accordingly, a thickness of the high refractive index layer adjacent to the auxiliary layer 30S, for example, a thickness of the first high refractive layer 30H1, may be small. Thus, flexibility of the first high refractive layer 30H1 may be improved.

According to an embodiment, a refractive index of the auxiliary layer 30S may be the same as or similar to that of the first high refractive layer 30H1. The refractive index of the auxiliary layer 30S may be in the range of about 1.7 to about 3. In detail, a refractive index of the auxiliary layer 30S with respect to a wavelength of 550 nm may be about 2.17.

Even in the present embodiment, the anti-reflection layer 30AR may include the metal layer 30M including a highly flexible material. That is, even in the present embodiment, the anti-reflection layer 30AR may include the metal layer 30M including aluminum. Thus, the flexibility of the anti-reflection layer 30AR increases, and, accordingly, even when the display apparatus 1 is folded, cracks may not occur in the anti-reflection layer 30AR or the occurrence of cracks may be effectively reduced.

Although the metal layer 30M is illustrated as being disposed between the first high refractive layer 30H1 and the first low-refractive layer 30L1 in FIGS. 7 and 9, the disclosure is not limited thereto. For example, the metal layer 30M may be disposed between the first low refractive layer 30L1 and the second high refractive layer 30H2.

FIG. 10 is a schematic cross-sectional view of a protective layer 30 included in the display apparatus 1 according to an embodiment. Because the protective layer 30 included in the display apparatus 1 according to the present embodiment is similar to the protective layer 30 described above with reference to FIG. 7, a difference from the protective layer 30 described above with reference to FIG. 7 will now be focused on and described. Reference numerals in FIG. 10 that are the same as the reference numerals in FIGS. 1 through 7 denote the same elements, and thus repeated descriptions thereof are omitted.

In the case of the protective layer 30 included in the display apparatus 1 according to the embodiment described above with reference to FIG. 7, the protective layer 30 includes the base layer 30BS, the anti-reflection layer 30AR, the anti-fingerprint layer 30AF, and the light-shielding layer 30LB. The anti-reflection layer 30AR includes the first high-refractive layer 30H1, the first low-refractive layer 30L1, the second high-refractive layer 30H2, the second low-refractive layer 30L2, and the metal layer 30M. Even in the case of the protective layer 30 included in the display apparatus 1 according to the present embodiment, the protective layer 30 includes the base layer 30BS, the anti-reflection layer 30AR, the anti-fingerprint layer 30AF, and the light-shielding layer 30LB, and the anti-reflection layer 30AR includes the first high-refractive layer 30H1, the first low-refractive layer 30L1, the second high-refractive layer 30H2, the second low-refractive layer 30L2, and the metal layer 30M.

However, in the protective layer 30 included in the display apparatus 1 according to the present embodiment, the metal layer 30M may be disposed between the first low refractive layer 30L1 and the second high refractive layer 30H2. That is, the protective layer 30 included in the display apparatus 1 according to the present embodiment is different from to the protective layer 30 described above with reference to FIG. 7 in terms of the location of the metal layer 30M, and the other structures are identical.

Even in the present embodiment, the anti-reflection layer 30AR may include the metal layer 30M including a highly flexible material. That is, even in the present embodiment, the anti-reflection layer 30AR may include the metal layer 30M including aluminum Thus, the flexibility of the anti-reflection layer 30AR increases, and, accordingly, even when the display apparatus 1 is folded, cracks may not occur in the anti-reflection layer 30AR or the occurrence of cracks may be effectively reduced.

Although the metal layer 30M is illustrated as being in direct contact with a low-refractive layer, for example, the first low-refractive layer 30L1 in FIG. 10, the disclosure is not limited thereto. For example, a layer including the same material as the material included in a high refractive layer may be interposed between the metal layer 30M and the first low refractive index layer 30L1.

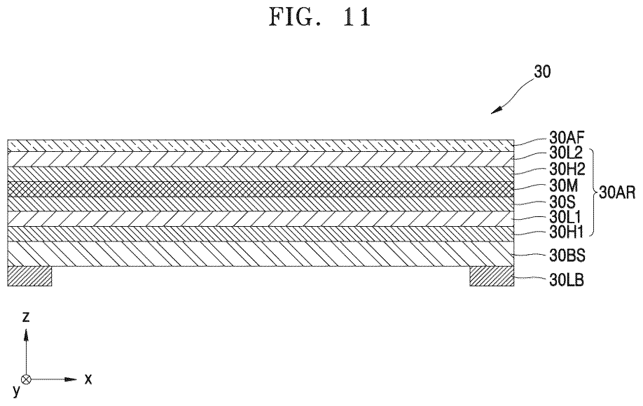

FIG. 11 is a schematic cross-sectional view of a protective layer 30 included in the display apparatus 1 according to an embodiment. Because the protective layer 30 included in the display apparatus 1 according to the present embodiment is similar to the protective layer 30 described above with reference to FIG. 10, a difference from the protective layer 30 described above with reference to FIG. 10 will now be focused on and described. Reference numerals in FIG. 11 that are the same as the reference numerals in FIG. 10 denote the same elements, and thus repeated descriptions thereof are omitted.

In the case of the protective layer 30 included in the display apparatus 1 according to the embodiment described above with reference to FIG. 10, the protective layer 30 includes the base layer 30BS, the anti-reflection layer 30AR, the anti-fingerprint layer 30AF, and the light-shielding layer 30LB. The anti-reflection layer 30AR includes the first high-refractive layer 30H1, the first low-refractive layer 30L1, the second high-refractive layer 30H2, the second low-refractive layer 30L2, and the metal layer 30M. Even in the case of the protective layer 30 included in the display apparatus 1 according to the present embodiment, the protective layer 30 includes the base layer 30BS, the anti-reflection layer 30AR, the anti-fingerprint layer 30AF, and the light-shielding layer 30LB, and the anti-reflection layer 30AR includes the first high-refractive layer 30H1, the first low-refractive layer 30L1, the second high-refractive layer 30H2, the second low-refractive layer 30L2, and the metal layer 30M.

However, in the protective layer 30 included in the display apparatus 1 according to the present embodiment, similar to the protective layer 30 described above with reference to FIG. 9, the anti-reflection layer 30AR may further include the auxiliary layer 30S. As described above, the auxiliary layer 30S may be interposed between the metal layer 30M and a low-refractive layer adjacent to the metal layer 30M. For example, the auxiliary layer 30S may be interposed between the metal layer 30M and the first low-refractive layer 30L1. The material included in the auxiliary layer 30S included in the display apparatus 1 according to the present embodiment and the refractive index of the auxiliary layer 30S according to the present embodiment have been described above with reference to FIG. 9, so a duplicate description thereof will be omitted. As described above, because the auxiliary layer 30S includes the same material as the material included in a high refractive layer, the auxiliary layer 30S may perform at least part of the role of the high refractive layer. Accordingly, a thickness of the high refractive index layer adjacent to the auxiliary layer 30S, for example, a thickness of the second high refractive layer 30H2, may be small. Thus, flexibility of the second high refractive layer 30H2 may be improved.

Even in the present embodiment, the anti-reflection layer 30AR may include the metal layer 30M including a highly flexible material. That is, even in the present embodiment, the anti-reflection layer 30AR may include the metal layer 30M including aluminum. Thus, the flexibility of the anti-reflection layer 30AR increases, and, accordingly, even when the display apparatus 1 is folded, cracks may not occur in the anti-reflection layer 30AR or the occurrence of cracks may be effectively reduced.

According to an embodiment of the disclosure as described above, a protective layer in which the occurrence of cracks may be reduced during folding of a display apparatus, and a display apparatus including the protective layer may be implemented. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A protective layer comprising:
a base layer;
a first high refractive layer disposed on the base layer and including titanium and niobium;
a first low refractive layer disposed on the first high refractive layer and including silicon;
a second high refractive layer disposed on the first low refractive layer, the first high refractive layer and the second high refractive layer including a same material;
a second low refractive layer disposed on the second high refractive layer, the first low refractive layer and the second low refractive layer including a same material;
an anti-fingerprint layer disposed on the second low refractive layer and including a perfluorinated compound; and
a metal layer interposed between the first high refractive layer and the first low refractive layer and including aluminum.

2. The protective layer of claim 1, wherein
the first high refractive layer includes titanium-niobium oxide, and
the first low refractive layer includes silicon oxide.

3. The protective layer of claim 1, wherein each of the first high refractive index layer and the second high refractive index layer has a refractive index of about 1.7 to about 3.0.

4. The protective layer of claim 1, wherein each of the first low refractive index layer and the second low refractive index layer has a refractive index of about 1.3 to about 1.6.

5. The protective layer of claim 1, wherein the first high refractive layer includes a substitutional solid solution in which a portion of titanium atoms of titanium oxide is replaced by niobium atoms.

6. The protective layer of claim 1, wherein
the first high refractive layer includes Ti₁₄Nb₃O₃₅, and
the first low refractive layer includes SiO2.

7. The protective layer of claim 1, wherein a thickness of the metal layer is about 0.5 nm to 20 nm.

8. The protective layer of claim 1, further comprising an auxiliary layer interposed between the metal layer and the first low refractive layer, the first high refractive layer and the auxiliary layer including a same material.

9. A display apparatus comprising:
a display panel;
a cover window disposed on the display panel; and
a protective layer disposed on the cover window,
wherein the protective layer comprises:
a base layer;
a first high refractive layer disposed on the base layer and including titanium and niobium;
a first low refractive layer disposed on the first high refractive layer and including silicon;
a second high refractive layer disposed on the first low refractive layer, the first high refractive layer and the second high refractive layer including a same material;
a second low refractive layer disposed on the second high refractive layer, the first low refractive layer and the second low refractive layer including a same material;
an anti-fingerprint layer disposed on the second low refractive layer and including a perfluorinated compound; and
a metal layer interposed between the first high refractive layer and the first low refractive layer and including aluminum.

10. The display apparatus of claim 9, wherein
the first high refractive layer includes titanium-niobium oxide, and
the first low refractive layer includes silicon oxide.

11. The display apparatus of claim 9, wherein each of the first high refractive index layer and the second high refractive index layer has a refractive index of about 1.7 to about 3.0.

12. The display apparatus of claim 9, wherein each of the first low refractive index layer and the second low refractive index layer has a refractive index of about 1.3 to about 1.6.

13. The display apparatus of claim 9, wherein the first high refractive layer includes a substitutional solid solution in which a portion of titanium atoms of titanium oxide is replaced by niobium atoms.

14. The display apparatus of claim 9, wherein
the first high refractive layer includes Ti₁₄Nb₃O₃₅, and
the first low refractive layer includes SiO2.

15. The display apparatus of claim 9, wherein a thickness of the metal layer is about 0.5 nm to 20 nm.

16. The display apparatus of claim 9, further comprising an auxiliary layer interposed between the metal layer and the first low refractive layer, the first high refractive layer and the auxiliary layer including a same material.

17. An electronic device comprising:
a display panel;
a cover window disposed on the display panel; and
a protective layer disposed on the cover window,
wherein the protective layer comprises:
a base layer;
a first high refractive layer disposed on the base layer and including titanium and niobium;
a first low refractive layer disposed on the first high refractive layer and including silicon;
a second high refractive layer disposed on the first low refractive layer, the first high refractive layer and the second high refractive layer including a same material;
a second low refractive layer disposed on the second high refractive layer, the first low refractive layer and the second low refractive layer including a same material;
an anti-fingerprint layer disposed on the second low refractive layer and including a perfluorinated compound; and
a metal layer interposed between the first low refractive layer and the second high refractive layer and including aluminum.
